(19) United States
(12) Patent Application Publication
(10) Pub. No.: US 2025/0141419 A1
(43) Pub. Date: May 1, 2025

(54) AMPLIFIER

(71) Applicant: Focusrite Audio Engineering Limited, High Wycombe (GB)

(72) Inventors: Steve BUSH, High Wycombe (GB); Simon JONES, High Wycombe (GB)

(21) Appl. No.: 18/837,878

(22) PCT Filed: May 31, 2023
(86) PCT No.: PCT/GB2023/051435

§ 371 Date: Aug. 12, 2024

(30) Foreign Application Priority Data
Jun. 1, 2022 (GB) 2208176.4
Dec. 7, 2022 (GB) 2218382.6

(51) Int. Cl. H03G 3/00; H03F 3/187; H03F 3/45; H03G 3/30

(52) U.S. Cl. CPC H03G 3/001; H03F 3/187; H03F 3/45475; H03G 3/3005; H03F 2200/03; H03F 2200/54

(57) ABSTRACT

There is provided an amplifier for amplifying audio signals. The amplifier comprises a plurality of stages. At least two of the stages of the plurality of stages are connected in series and each of the at least two stages is a gain stage each provided by a preamplifier stage. The at least two stages are arranged, in use, to apply gain to an input signal provided to the amplifier.

### FIELD OF THE INVENTION

The present invention relates to an amplifier and the amount of gain achievable using the amplifier, such as in relation to amplification of audio signals.

### BACKGROUND

The use of a microphone or another audio line feed is generally passed through some form of amplifier to apply gain to an input signal provided from the microphone of audio line feed. Depending on the circumstances, such as strength of an input signal or what is wanted from an output signal, as an alternative or additionally, other processing may be applied by an amplifier.

The input could be a sensitive microphone; non-sensitive microphone; musical instrument, such as a guitar, keyboard or synthesiser; or an audio signal generator, such as application operating on a computer or smartphone. Depending on the input and what the desired output may be, a user may have a specific aim they wish to achieve with an amplifier. This may result in a user making use of an amplifier with functionality tailored to that aim. However, this increases costs for users since this requires them to have multiple amplifiers, each dedicated to a specific purpose or particular input. This creates a need for an amplifier that is able to function for a wide range of uses or input types.

Such amplifiers that are able to handle a range of uses exist or input types. However, when using such amplifiers, due to the many possible input types, there is a large variation in sensitivity or strength of the signal provided from the input types. Users expect high quality performance across a range of input types they could use with the amplifier. Typically, this means a wide gain range is needed to be able to produce a suitable output. This is technically challenging to achieve.

The core of the technical challenge centres on providing enough gain range to handle highly sensitive audio feed inputs, such as guitar inputs, while also handling low sensitivity inputs, such as low gain microphones. While amplifier chip manufacturers are aware of this issue, providing an amplifier chip with a wide gain range, of a suitable quality and at a cost usable by amplifier manufacturers and accessible to users has proved to not yet be possible.

In view of this, other means have been developed to supplement the gain available from an amplifier. One such means is to apply gain digitally through the amplifier firmware. This is achieved by digitally amplifying the signal output after conversion from an analogue signal to a digital signal by an analogue to digital converter (ADC). However, much like digital zoom able to be applied by a camera, applying digital amplification degrades the quality of the signal. This is because it is effectively an artificial amplification of a fixed signal. Additionally, there is a preference amongst users for applying analogue solutions due to the (at minimum) perceived higher quality sound output this provides. This is part of the same desire and reasoning causing a resurgence in vinyl records.

An analogue solution that has been developed is a booster that is connected between, for example, a microphone, and an amplifier. Such boosters apply gain to the signal before it reaches the amplifier to artificially amplify the signal before it undergoes the gain applied by a conventional amplifier via use of an amplifier chip. However, to make these boosters attractive to users, they need to be low cost, which means the circuit build and amplification quality is low. This has a negative impact on the output of the boosters, which causes a knock-on effect of lower quality sound output after any further processing that is applied.

Accordingly, there is a need to increase gain range of an amplifier while minimising degradation of signal quality. This is something that the existing firmware amplification and boosters have not been able to achieve.

### SUMMARY OF INVENTION

We have developed an amplifier that provides an amplification stage integrated into an amplifier. This is typically provided as an intermediate stage between two stages of the amplifier. A first stage receives an input signal and a second stage provides an output signal. The intermediate stage is connected between the first stage and the second stage.

Instead of providing extra gain or amplification outside of an existing amplifier, as is the case with digital gain applied through the use of firmware and a booster inserted in a feed before the signal reaches an amplifier, this is applied as an intermediate stage of an amplifier. This is able to be achieved by applying an intermediate stage to a pre-existing multistage amplifier or multistage amplifier chip or by integrating an intermediate stage into a multistage amplifier chip design.

Due to this, gain is able to be applied, in use, by the at least two stages, to an input signal provided to the amplifier. In other words, there are at least two stages that are intended to provide gain, such as functioning to provide gain, being configured or arranged to provide gain in use, and/or have a (primary) purpose to provide gain. This result can also be achieved by with only two stages, namely the first stage and intermediate stage referred to above, when configured appropriately. It is therefore not always required to include the second stage referred to above. Further, each stage, whether there are (only) two, (only) three or more stages, could be provided separately from each other in terms of circuity or in groups as well as in an integrated form. Typically however, they all form part of only a single unit as an amplifier without any cabling and connects, such as XLR connects or similar connections, or intervening wiring other than signal traces on a printed circuit board (PCB) or connections between PCBs within the same installation for example.

In view of this, there may be provided an amplifier comprising at least two gain stages connected in series, such as at least two analogue gain stages connected in series, the amplifier typically being a multistage preamplifier having at least two analogue gain stages connected in series. This is able to be implemented by an amplifier according to the first aspect below.

According to a first aspect, there is provided an amplifier for (i.e. suitable for) amplifying audio signals, comprising: a plurality of stages, at least two of the stages of the plurality of stages being connected in series and each of the at least two stages being a gain stage, the at least two stages being arranged, in use, to apply gain to an input signal provided to the amplifier.

This provides a benefit of allowing completely analogue gain application, thereby avoiding deterioration of signal quality caused by digital amplification while also allowing high quality gain to be provided by an amplification stage that is designed to apply large gain at low noise, as is the case for most preamps. Further this provides the ability to significantly increase (such as an increase of 300% or more) in the amount of gain able to be applied to an input signal while maintaining signal quality at a level acceptable to a user. In the arrangement of the first aspect this is able to be achieved at low additional cost.

By the term “connected”, it is intended to mean electrically connected and/or in (electrical) communication with. It is intended for the term “gain” to mean amplification and/or attenuation of signal strength, such as by alteration of the amplitude of the signal and/or to vary the level of the signal. Additionally, as mentioned above, it is intended the amplifier is self-contained instead of being provided by disparate, and separately available or purchasable consumer items, such as an existing amplifier being connected with a microphone booster like those described above.

While the plurality of stages may be any type of stage suitable for applying gain, (one, two, three or more, such as a plurality, or each of) the at least two stages are (each provided by a) preamplifier stage(s). Preamplifiers or “preamps” are usually known for converting a (relatively) weak electrical signal into a noise-tolerant audible output signal. In other words, preamplifiers are low signal, low noise amplifiers that typically provide a flat response, so are capable of receiving a signal at a low level and increasing that level to a usable level, such as one that can be used to drive an analogue to digital converter, ADC, or fed into a power amp while maintaining a low noise level.

On the other hand, amplifiers of other varieties (such as power amplifiers or power amps, ADC drivers, equalisers or filters) are usually known. Power amplifiers are used for increasing the power of the output level of any signal, causing additional or increase in noise while applying minimal gain. Further, power amplifiers typically amplify noise by the same or a similar amount to the amount of amplification applied to the signal. Power amplifiers can maintain a low noise level, but this is only due to also providing comparably low gain.

ADC drivers typically provide small amounts of positive gain or negative gain (i.e. attenuation), such as (within a range of) 0 decibels (dB), positive 10 dB and/or/to negative 10 dB. An ADC driver is (primarily) arranged in use to be capably of driving high currents. Only small amounts of gain are typically applied because applying larger amounts of gain generally reduces the bandwidth over which the ADC driver can operate when provided by an amplifying stage. This reduction in bandwidth can be limited by using a stage of a higher specification, but such stages are typically prohibitively expensive.

Equalisers or filters may be used when the input signal being received vary from device to device that provides the input. These may include, for example, magnetic cartridges, moving coil cartridges or phonographic (also referred to as “phono”) cartridges. These are used to adjust the frequency response to provide an output with improved consistency when there is an inconsistent input from a device or between devices (capable of) providing an input.

In view of the possible amplifier stages that can be implemented, using preamp stages in the amplifier according to the first aspect limits the amount of noise the application of gain adds to the input signal being amplified since these are typically configured to provide minimal noise. For corresponding reasons, the amplifier may (as a whole) be a preamplifier.

The plurality of stages can provide an output from the at least two stages. However, typically, the plurality of stages includes an ADC driver stage. As set out above, this is able to drive higher currents relative to other stages, which allows a low impedance drive to be provided to an ADC for efficient interaction with an ADC. Typically, this means the ADC driver stage is connected at a downstream end (i.e. at an output end) of the at least two stages. The ADC driver stage is usually also connected in series with the at least two stages. An ADC driver is typically a stage, such as an output stage, of an amplifier that is connected to or connectable, in use, to an ADC or, in use, is capable of providing a suitable input to an ADC.

The plurality of stages may each be part of a larger system, or all individual components provided in separate circuits or chips. Typically, at least one stage of the at least two stages and the ADC driver are part of an integrated circuit and at least one stage of the at least two stages is connected between a first output of the integrated circuit and a first input of the integrated circuit, the first output and first input being between the at least one stage and ADC driver of the integrated circuit. For example, at least one stage of the at least two stages and the ADC driver may be part of an integrated circuit. In such an example, a further at least one stage of the at least two stages may then be connected between a first output of the integrated circuit and a first input of the integrated circuit, the first output and first input being between the at least one stage and ADC driver of the integrated circuit. This allows enhancement of amplification able to be provided by a pre-existing amplification or preamp circuit or chip. In other words, this provides a boost to the amplification able to be provided. Further, because the at least one gain stage is connected between an existing output and input of the circuit, this allows this additional gain stage to be a low-cost stage and to be added at low cost due to the simplicity of installation. This is due to a reasonably high-quality gain stage to be provided that is independent of the integrated circuit, allowing a relatively low noise and relatively high gain stage to be implemented that could not be achieved at the same cost if trying to integrate the at least one gain stage into the integrated circuit.

The first output and first input of the integrated circuit may be included at manufacture of the integrated circuit. For example, the first output and first input of the integrated circuit may be terminals of the integrated circuit. This provides a simple connection mechanism that does not require the integrated circuit itself to be modified, which would potentially damage the integrated circuit. This also provides the ability to retrofit the at least one gain stage connected between the first output and first input, such as by repurposing pin connections on the integrated circuit. For example, this may be achieved by providing this connection across a capacitance “breakout”, i.e. between two pins that are intended, by the integrated circuit manufacturer in their expected or standard circuit design or recommendation, to be used to have a capacitance connected across.

Control of each stage of the plurality of stages may be provided in by any suitable means. Typically, the integrated circuit includes a second output connected to a control input of the at least one stage connected between a first output and the first input of the integrated circuit, the at least one stage connected between a first output and the first input of the integrated circuit being arranged, in use, to be controllable based on a signal issued from the second output of the integrated circuit. This allows control of the at least two stages and the ADC stage to be provided by interaction only with the integrated circuit. This keeps the number of connections needed to control the amplifier to a minimum, since no further connection is needed to the stage connected between the first output and first input of the integrated circuit.

The amount of gain providable by the at least two stages may be fixed, non-modifiable or continuous. Typically, the at least two stages are arranged in use to selectively apply gain to the input signal. This means one or both of the at least two gain stages do not need to provide gain at all times (during operation of the amplifier), or provide a minimum gain, such as 1 dB. This provides an ability to vary the gain applied to an input signal to the amplifier, allowing a user to vary the output to suit their needs.

The at least two stages may be arranged in use to apply modifiable gain to the input signal. This allows an appropriate or desired amount of gain to be applied during use, which broadens number of uses for which the amplifier can be used.

Typically, the at least two stages include a first stage and a second stage. The at least two stages may include only (i.e. only include) the first stage and the second stage. When the at least two stages only have the first and second stages, this limits the cost of the stages that apply gain.

The first stage and second stage may be able to apply the same amount of gain, and/or have the same capabilities in terms of applying gain. Typically however, the first stage and the second stage each have a gain range, the first stage having a different gain range to the (gain range of the) second stage. This means the first stage and second stage can be a different quality, and, therefore, different cost, of a gain stage, allowing the amplifier's purpose to be fulfilled without, for example, doubling the cost of the gain stages by implementing the second stage. Further, this allows a tailoring of where noise effects due to the application of gain by each of the first stage and second stage to be managed to achieve the highest quality output signal from the at least two gain stages while having gain stages with realistic and practical noise responses.

The first stage and second stage may be arranged in any order or may receive the input signal provided to the amplifier in any order. Typically though, the input signal provided to the amplifier passes to the first stage before passing to the second stage, the gain range of the first stage being greater than the gain range of the second stage. In other words, the first stage and second stage is typically connected with the first stage first (i.e. closer to an amplifier input end or upstream end of the plurality of stages) and the second stage second (i.e. closer to an amplifier output end or downstream end of the plurality of stages) relative to each other. This allows the second stage to be a lower quality (and therefore lower cost) stage than the first stage while still maintaining overall gain range without significantly affecting quality. This is because, by locating the higher quality application of gain upstream minimises degradation of the signal quality when gain is initially applied, allowing the signal to still have little degradation (such as additional noise) once gain has already been applied and before further gain is applied. This is instead of the degradation being more significant if the opposite arrangement were to be used.

The gain able to be applied by the first stage and able to be applied by the second stage may be appliable and modifiable in any suitable manner, such as on a continuous scale. In a conventional amplifier or preamplifier that, for example, implements a preamplifier stage and an ADC driver stage, the steps in the gain able to be applied by stages varies (which can also be referred to as the precision or accuracy with which the gain is able to be applied), moves from coarse to fine. In other words, the first, earlier or upstream stage has larger gain steps than the second, later or downstream stage. For the amplifier according to the first aspect, typically, the gain of the first stage and the gain of the second stage are modifiable in gain steps, the gain steps of the first stage are smaller than the gain steps of the second stage. This reverses the conventional order by having a finer and then a coarser adjustment. This provides an ability for greater and more specific and precise tailoring of the gain able to be applied by the first stage while minimising the complexity of the second stage, and thereby minimising is setup and cost.

If accompanied by an ADC driver stage, typically, the gain of this (third) ADC driver stage is modifiable in gain steps, the gain steps of the ADC driver stage typically being smaller than the gain steps of the first stage (and of the second stage). This then implements a medium, coarse and fine gain step adjustment ability when there is a first stage, second stage and ADC driver stage connected in that order. We have found this arrangement to be beneficial in terms of amplifier design and fabrication.

The second stage may be provided by any form of gain stage. Typically, the second stage is a differential amplifier including a potential divider having a first impedance and a second impedance separated by an output of the potential divider, at least one of the first impedance and the second impedance is a variable impedance. This provides a simple means of providing an ability to modify the gain able to be applied by the second stage. This is because varying the impedance of at least one of the first impedance and the second impedance will vary the amount of gain applied, in use, by the second stage. While the impedance may be provided by any form of impedance, typically the first impedance is provided by a first resistance (such as being provided by a first resistor) and/or the second impedance is provided by a second resistance (such as being provided by a second resistor).

The variable impedance may be provided by any form of impedance that is variable, such as a variable resistor. Typically, the variable impedance includes a plurality of impedances (one or more of which may be one or more resistors) connected in parallel, each of at least one of the impedances of the plurality of impedances is connected to a switch operable, in use, to set connectivity of the respective impedance. This provides the ability to provide stepped gain in the second stage, allowing discrete steps of known gain amounts to be applied in use. This is instead of continuous range being available. The stepped gain makes application of gain more repeatable and therefore provides a greater reliability to a user.

When the second stage is connected between a first output and a first input of the integrated circuit and the second stage is controllable based on a signal issued from the second output of the integrated circuit, each switch may be controllable with the signal issued from the second output. Of course, one or more (including only one or all of the switches) may be controllable independently and separately to any signal issued from the second output of the integrated circuit, such as by direct control from software, firmware or a user, which may bypass any integrated circuit should one be present.

In some cases, the second stage may be a non-balanced amplifier. Typically, the differential amplifier is a balanced differential amplifier. This provides the ability for the second stage to apply gain to a signal it receives containing two opposite phase portions (i.e. a first portion, for example provided as a sinusoidal wave, and a second portion, for example provided as a further sinusoidal wave, with the inverse phase), which boosts, and potentially doubles, the gain able to be applied by the second stage.

The amplifier may further comprise a controller arranged, in use, based on user input of a gain level, to set the gain of the at least two stages. This allows a user to apply the amount of gain they wish to apply through a (centralised) control mechanism. Additionally or alternatively, the controller may be able to set the gain level itself based on the signal input to the amplifier (such as without user interaction, but simply from the audio input signal). This would apply a form of “autogain” where the amplifier is able to determine and set an amount of gain to be applied.

The controller may be arranged in use to select the gain level to be applied by at one or more of the at least two stages based on input signal strength and/or user input. Further this may be based on gain applied by one or more other stages and/or predetermined characteristics of a desired output signal.

The controller may be implemented by a form of software, such as firmware.

The controller may operate in any suitable manner, such as by issuing analogue signals. Typically however, the controller is arranged, in use, to issue a digital signal to set the gain of the at least two stages. This provides digital control of the amount of gain while allowing the signal passing through the amplifier to be kept as an analogue signal. Additionally, this provides a repeatable and reliable mechanism of applying gain, that can be dynamic and reactive to inputs.

The plurality of stages may be arranged, in use, to provide a gain range of at least 65 dB. With an increase of 3 dB in gain increasing the gain by 100%, this provides significantly more gain to an analogue signal than existing amplifiers, that may have a gain range for an analogue only signal of around 55 dB. The plurality of stages may, in use, provide a gain range of up to 100 dB, up to 90 dB, up to 80 dB or up to 70 dB, and/or at least 60 dB. The gain range able to be provided by the plurality of stages may be 68 dB, 69 dB or 70 dB.

The input signal may be converted from an analogue to a digital signal as it passes through the plurality of stages. Typically, the plurality of stages are arranged, in use, to maintain input signal provided to the amplifier, when provided as an analogue (audio) signal, as an analogue (audio) signal. This allows gain to be applied to an analogue only signal, which helps maintain the quality of the signal.

The amplifier may further comprise an input for receiving an audio signal and (additionally or alternatively may further comprise) an output for outputting an output signal, the plurality of stages being connected between the input and the output.

The plurality of stages may include: a first stage configured as a preamplifier and arranged in use to receive an input signal and to output an amplified signal; a second stage configured as an ADC driver and arranged in use to issue an output signal; and an intermediate stage configured as a preamplifier and connected between an output of the first stage and an input of the second stage, thereby receiving the amplified signal, wherein the intermediate stage is arranged in use to apply secondary amplification to the amplified signal and output a further amplified signal, the second stage being arranged to receive the further amplified signal as an input; and the amplifier may further comprise a controller arranged in use to select a gain level to be applied by the intermediate stage, thereby modifying a cumulative gain across by the amplifier. The placement of the intermediate stage allows low cost amplification to be provided in the intermediate stage. This is because it does not need to include the high current amount that would be needed if it was the final stage before an ADC so as to be able to drive the ADC. This means the focus of the intermediate stage amplification can be on having low noise to minimise negative impact on signal quality. The placement also allows the gain range of the intermediate stage to be relatively modest since it does not need to provide the first step up to any input signal. As such, a good balance is able to be struck between noise capability, gain range, current capabilities and cost of amplification. It is intended the first stage referred to in this paragraph corresponds to the first stage referred to above, and to an upstream stage of the at least two stages. Further, it is intended the intermediate stage referred to in this paragraph corresponds to the second stage referred to above, and to a stage downstream of the first stage.

According to a second aspect, there is provided a system for amplifying audio signals, the system comprising: an audio signal input; an amplifier according to the first aspect, the amplifier comprising a plurality of stages, at least two of the stages of the plurality of stages being connected in series and each of the at least two stages being a gain stage, and an output, the plurality of stages being connected between the output and the audio signal input, wherein the at least two stages are arranged, in use, and to apply gain to an input signal provided to the audio signal input; an ADC connected to the output of the amplifier; and an output connected to the ADC and connectable, in use, to an output device; the output being connected to the ADC.

The system may further comprise a controller connected to the amplifier, the controller arranged, in use, based on user input to control operation of the amplifier.

### BRIEF DESCRIPTION OF DRAWINGS

Example amplifiers are described in detail below with reference to the accompanying figures, in which:

FIG. 1 shows a schematic of an example prior art amplifier;

FIG. 2 shows a schematic of an example amplifier;

FIG. 3 shows a block diagram of a part of an example amplifier chip;

FIG. 4 shows a further block diagram of a part of an example amplifier chip;

FIG. 5 shows a first part of an example amplifier circuit diagram;

FIGS. 6A and 6B show second and third parts of the example amplifier circuit diagram;

FIG. 7 shows a plot of system gain against dynamic range for various amplifier arrangements;

FIG. 8 shows a plot of system gain against dynamic range for an example amplifier and a comparative example amplifier;

FIG. 9 shows a fourth part of the example amplifier circuit diagram;

FIG. 10 shows a fifth part of the example amplifier circuit diagram;

FIG. 11 shows a sixth part of the example amplifier circuit diagram;

FIG. 12 shows a seventh part of the example amplifier circuit diagram;

FIGS. 13A and 13B show eighth and nineth parts of the example amplifier circuit diagram; and

FIG. 14 shows a tenth part of the example amplifier circuit diagram.

### DETAILED DESCRIPTION

One of the parameters of performance of an amplifier is the gain range of the amplifier. We have previously increased the capability of amplifiers so they can function with inputs from the quietest singer with a low sensitivity microphone to the loudest guitar being thrashed at a concert. With an amplifier according to an aspect disclosed herein, we have increased the input headroom to handle louder signals and extended the gain range to provide functionality with lower amplitude signals. A gain range of, for example, 68 dB, 69 dB or 70 dB has been achieved over a previously available 56 dB range, which represents an increase in gain of between 500% and 400% in the amplifier gain capabilities.

To enhance the user experience, instead of a purely analogue design, a hybrid analogue with digital control has been implemented. This allows for advanced features, such as remote control and automatic level adjustment. While beneficial, such a hybrid approach is not required in all implementations of an amplifier according to an aspect disclosed herein.

To achieve the wide gain range in the amplifier, according to an aspect disclosed herein, in addition to a (first) preamp stage (also referred to as a “first stage”), we have added a second preamp stage (also referred to as a “second stage”). This provides a multistage amplifier. This allows an increase in the gain provided by the first stage, which, is typically a low noise preamp.

In various examples, the second stage adds extra levels of gain via digital control, extending a gain range of a multistage amplifier from 43 dB to 68 dB, 69 dB or 70 dB (depending on the specific implementation). In other examples, the second stage may apply a fixed amount of gain, may have a different form of control, such as an analogue control or simple on/off gain.

Using this arrangement, the resolution achievable across this gain range is 1 dB. By this we intend to mean that gain is able to be modified in steps of 1 dB across the entire gain range. In some examples, the resolution may be a resolution of 3 dB, 6 dB or some other increment. Importantly, this gain range increase and resolution is all achieved in the analogue domain. Along with control appliable through firmware, this creates a hybrid analogue amplifier with digital control.

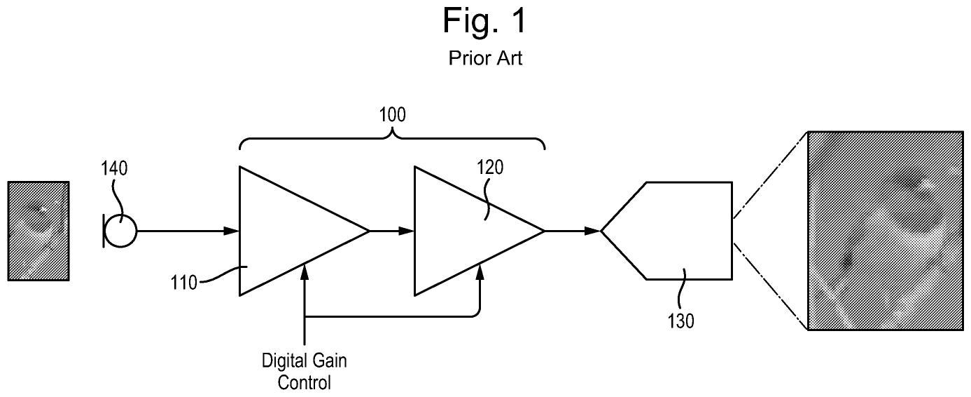

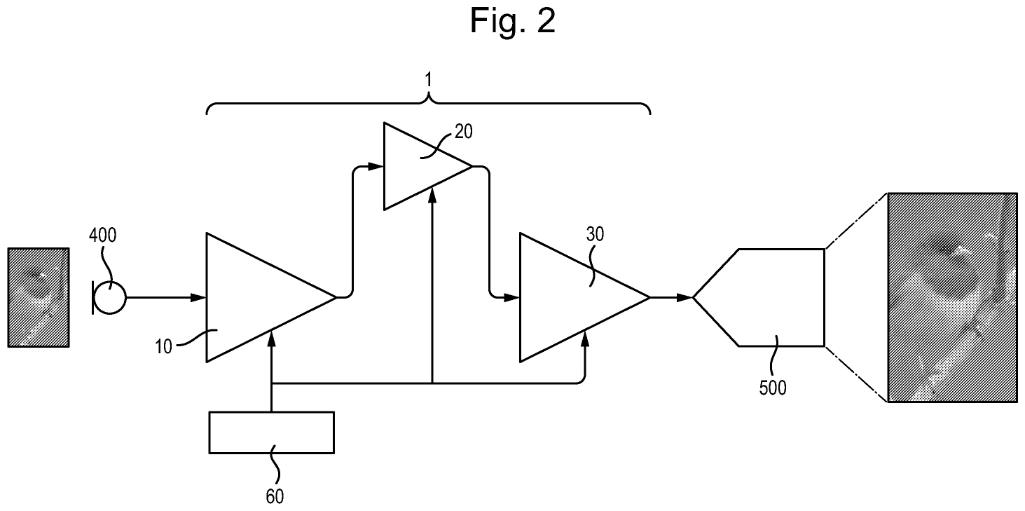

An advantage of analogue gain being applied in the amplifier according to an aspect disclosed herein over digital gain is that the full range of the ADC is usable. This means the resolution is the same over the complete gain range, and no detail is lost. This can be seen by the comparative examples shown in FIG. 1 and FIG. 2.

FIG. 1 shows an example of adding extra gain after the ADC through a software implementation when a conventional (i.e. prior art) digital controlled amplifier is used. This figure shows a two-stage amplifier 100 with an input feed from a microphone 140 applying this approach loses detail due to how the output of the amplifier is handled.

In the prior art example shown in FIG. 1, the first stage 110 of the amplifier is a preamp. The second stage 120 is an ADC driver. Each stage applies gain (which can be positive or negative, i.e. to respectively amplify or attenuate the signal) to the signal passing through it. In the example provided a gain range is 42 dB across the two stages of the amplifier. The amount of gain applied is controlled digitally based on user input either by a physical pot or dial on the amplifier or through inputs in software running the amplifier. The output from the second stage is passed to an ADC 130, which converts the analogue signal provided to it by the second stage into a digital signal.

To be able to provide further gain to the signal output of the ADC 130, only part of the full bit range of the ADC is able to be used when applying full gain with the amplifier 100. While the ADC used in this example shown in FIG. 1 and the example shown in FIG. 2 is typically a 24-bit ADC, due to the limited capability of the example shown in FIG. 1, adding further gain on the signal output from the ADC therefore has limited detail.

In FIG. 1, as an example of the loss of detail effect, a photograph is shown. The photograph is shown at a small scale at the input end. Through applying the firmware amplification process according to this prior art example, the image output (at the output end) may be missing part of the image, representing a clipped signal, and the image quality is decreased with the image becoming pixelated.

An audio equivalent occurs when applying this process to an audio signal. This is typically an increase in noise and/or distortion of the audio signal. As an example, the ADC bit range may have a 5 Volt (V) range of volt swing. When applying full gain using first stage 110 and second stage 120 of the amplifier 100, the output level provided to the ADC 130 may only provide enough signal strength (e.g. enough voltage) to fill a fifth of the ADC output bits, such as about 1 V of signal being provided to the ADC. As such, with that level of input, the ADC is incapable of providing an output from all its output bits. The means the output is limited to a reduced number of bits, causing a low resolution to be used, thereby providing the equivalent of less signal with which to conduct further processing. This explains why there is a degradation in quality, since the signal to noise ratio within that output will be more significant than is a broader bit range signal were able to be produced.

In FIG. 2, there is an example amplifier generally illustrated at 1 in accordance with an aspect disclosed herein. In this example, there are a plurality of stages. Two of these stages, in this example, are (electrically) connected in series. These stages are predominantly intended to provide gain during operation. These are provided by a first stage 10 and a second stage 20. The first stage is a preamp, like the first stage 110 of FIG. 1. The second stage 20 is also a preamp stage. In other examples this second stage is able to be a stage that provides amplification/gain in a different manner to that of a preamp. Some examples may also have further stages connected in series with these two stages arranged to provide the same functionality as the first and second sage.

In addition to the first stage 10 and second stage 20, the example shown in FIG. 2 includes a third stage 30. As with the second stage 120 of the prior art example shown in FIG. 1, this third stage is an ADC driver stage. Various example may exclude this stage.

In combination, the first stage 10 and third stage 30 of the amplifier 1 shown in FIG. 2 are able to provide a gain range of 42 dB or 43 dB. Additionally, in the example shown in FIG. 2, the second stage 20 is configured, in use, to be able to apply one of three different gain levels. These are 1 dB, 14 dB and 24 dB. This means a full gain range of 66 dB or 67 dB is possible when using the second stage as well as the first and third stages.

In other examples, other gain levels may be possible. A further example would be the second stage 20 being able to provide gain levels of 0 dB, 13 dB and 27 dB. When the combination of the first stage 10 and third stage 30 provide a gain range of 42 dB or 43 dB, the integration of the second stage provides a full gain range of 69 dB or 70 dB.

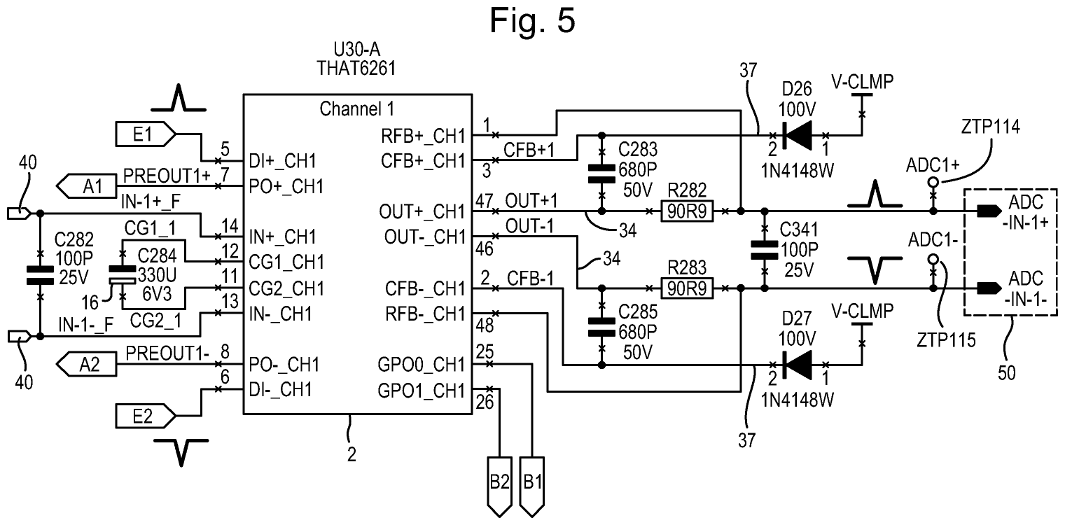

The amplifier 1 is able to receive an audio signal from an input (shown at reference numeral 40 in FIG. 5). This is typically received from a microphone 400 or other input, such as a line or instrument input. This signal passes to the first stage 10. Gain is applied by the first stage based on the amount of gain it is set to apply. This signal is output from the first stage to the second stage 20. The second stage is connected in series with the first stage. From this connection to the first stage, the second stage (also referable to as the “intermediate stage”) is able to apply gain to the analogue signal it receives from the first stage 10 before the signal is output from the second stage to an input of the ADC driver stage 30. An ADC 500 is connectable in use to an output (shown at reference numeral 50 in FIG. 5) from the amplifier 1, from which the signal output from the ADC driver stage is able to be passed. Due to the additional gain applied by the second stage, the full bit range of the ADC is able to be used when the signal is passed from an ADC on for further processing or output.

As can be seen from above, the gain of the amplifier 1 is able to be applied in several levels. This enhances the dynamic range of the amplifier as a whole, with the dynamic range representing the signal to noise ratio identifiable in an output signal. Of course, in various examples, the gain able to be applied by the any one stage or combination of stages may be fixed, simply able to be switched on and off, or may be incrementable in different step sizes.

As noted in relation to the examples above, in the example shown in FIG. 2, the second stage 20 is able to apply three different levels of gain. In other examples, a different number of levels of gain may be available or no levels of gain (i.e. only a single gain amount) are applied. Transition between ranges is typically controlled by firmware operating the amplifier 1 (by which we intend to mean firmware operating the first stage 10 and ADC driver stage 30 as well as the second stage).

This control of the gain able to be applied, in the example shown in FIG. 2, by the second stage 20 is achievable using a controller 60 of the amplifier 1. The functionality of the first stage 10 and ADC driver stage 30 are also controlled by the controller in this example. In other examples, each stage may be controlled independently, by a different means, or may be directly controlled by a user.

How and when to apply the gain levels available from the second stage 20 is able to be chosen. In some examples, the second stage provides its minimum gain while the first stage 10 provides gain up to the level of the middle gain level (for example 14 dB) of the second stage. At this point, the second stage is set to applying that level of gain and the first stage is returned to providing no gain. As gain is to then be increased further, the same is applied until the combined amount of gain applied by the second stage and the first stage is equal to the highest gain level (for example 24 dB) able to be applied by the second stage. The second stage is then set to apply this gain range and the first stage returned to applying no gain and then the gain that applies is steadily increased as further gain is to be applied.

An alternative to this is for the second stage 20 to apply the minimum gain, the gain applied by the first stage 10 to be increased to, for example, one third of the full gain range; the middle level of gain to then be applied by the second stage with the gain applied by the first stage dropped to an equivalent of the difference between the middle level gain of the second stage and the one third of the fill gain range. This can then be applied while (again) increasing the gain applied by the first stage until the overall/cumulative gain applied by the first stage and third stage 30 corresponds to, for example, two thirds of the full gain range. At this point, the second stage is switched to applying the highest level of gain and the first stage gain reduced to provide a cumulative gain of the same level as previously, i.e. two thirds of the overall gain range. Increasing the gain over the final third of the gain range is then achieved by increasing the gain of the first stage.

Overall, as set out above, the gain is able to be incremented in 1 dB steps. This is achieved using the steps set out above for the second stage 20, and a combination of the first stage 10, for example, incrementing gain in steps of 3 dB between 0 dB and 39 dB, and the ADC driver stage, for example, incrementing gain in steps of 1 dB between −8 dB (so an attenuation of 8 dB instead of an amplification of 8 dB) and −5 dB. In other examples, how the gain increments of the amplifier 1 as a whole are achieved may be provided in a different manner or different combination.

Regarding the ADC driver stage 30, in the example shown in FIG. 2, this is able to drive high currents. A typical current level at which the ADC driver stage operates is between about 2 milliamps (mA) and 5 mA, but this is capable of operating up to about 20 mA. In contrast, the first stage 20 is only capable of operating up to about 5 mA. The ADC driver stage being able to drive high currents is because, typically, a sigma-delta sampling circuit is being driven, which often need high currents. This is due to such circuits having a low impedance input of around 2000 Ohms (Ω), for example. This is, however, determined by the specifics of the ADC being used.

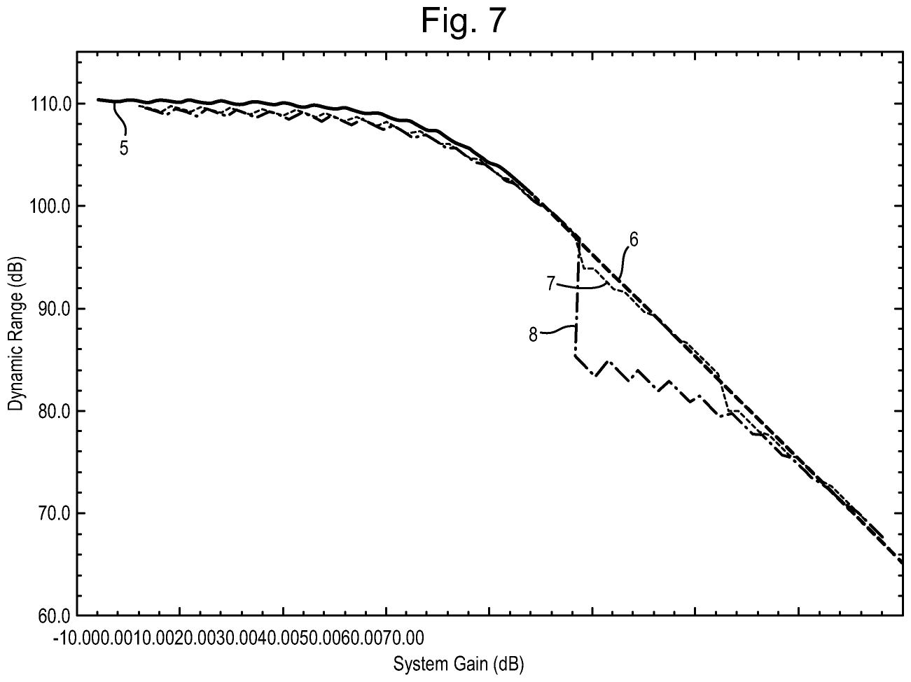

Numerous other examples are possible with the specific implementations typically being determined by the optimum performance able to be achieved across the various stages. A factor that contributes to what determines the point at which to apply the gain levels of the second stage 20 is the effect applying gain via the second stage has on the observable noise floor (identifiable by analysing the signal output from the amplifier 1). Each time the gain level is raised in the second stage, the noise floor across the amplifier (in this case including the first stage 10, third stage 30 and second stage) is stepped up. It is desirable to keep the step size to a minimum. This is why multiple gain levels, can, in some examples, be preferred since it keeps the step size in the noise floor level smaller. A demonstration of this can be seen from FIG. 7 and the associated sections below. A balance is therefore achieved between providing more gain levels to reduce noise floor step size and cost and technical difficulty in implementing more gain levels.

Implementing a second stage 20 to provide gain was a technical challenge. This is because, in the implementation applied, it involved inserting an amplifier stage between two other amplifier stages provided as part of an integrated circuit. This could be achieved in other ways, such as by designing an amplifier (for example one on an integrated circuit) from first principles with a first stage 10 and third stage 30 along with a designed-in second stage 20, or by using singular stages (each on an independent integrated circuit, for example) that are coupled together using circuity or wiring. Regardless, these technical challenges would exist. This is because the challenges would be common to each approach. These include ensuring the various components are compatible with each other and their needs, such as voltage rail requirements; and that the circuit can be designed in a way so as not to cause damage to other components, cause latching or other detrimental effects. Additionally, the second stage can be low noise while also having its components available at a non-prohibitive cost and providing the ability to handle suitable gain level changes to minimise noise floor step sizes on operation or switching.

Returning to the visual example provided in relation to FIG. 1, in the example shown in FIG. 2, the addition of the second stage allows the signal strength able to be provided to the ADC 500 (such as at full gain across the amplifier 1) to be enough to fill the ADC bit range. This may, for example, be a 5 V input. This then converts to a full 5 V digital output that does not need extra amplification by use of the full resolution of the ADC by using all the ADC bits. Accordingly, the output from the ADC includes as much detail in the output as possible and means the signal to noise ratio of that output is kept as low as possible.

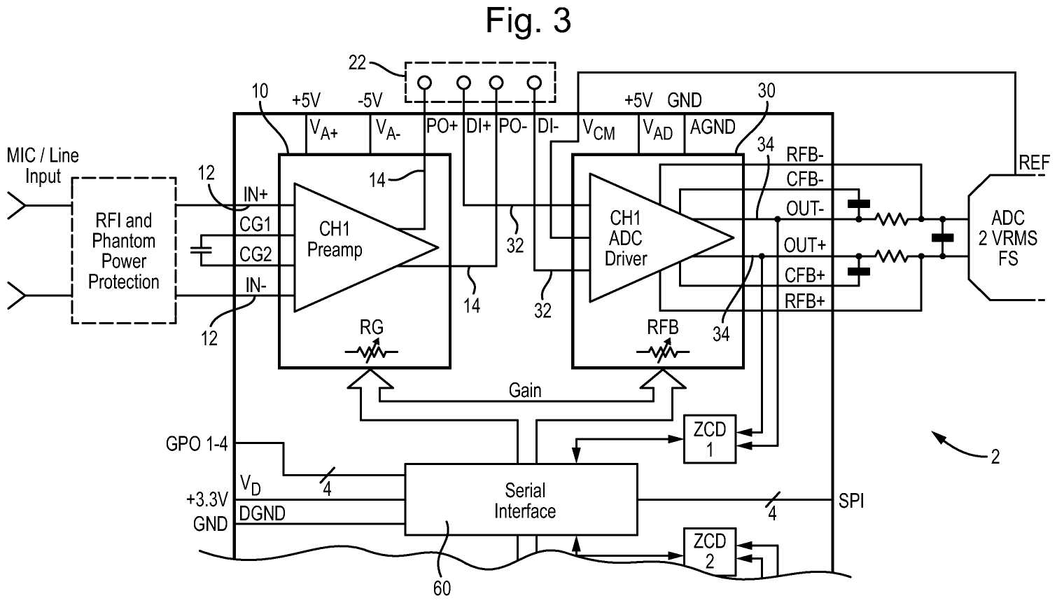

In the examples shown in FIGS. 3 to 6 and 9 to 14 a THAT 626x amplifier chip and other components are shown providing the amplifier 1 that has been supplemented with the second stage 20. The specific chip detailed in these examples is a THAT 6261 chip, but, in other examples, different varieties or other chips can be used.

The amplifier chip 2 portion of the amplifier 1 shown in the examples in FIGS. 3 to 5 has two stages as set out above. These are a preamp as a first stage 10 and an ADC driver stage 30 as the other of the two stages. As shown in FIG. 3, the first stage has two preamp input channels 12 that are arranged, in use, to receive an input from a microphone or other line input.

The first stage 10 also has two preamp output channels 14. Operation of the first stage 10 preamp can cause a DC voltage build-up. To address this, the standard approach is to provide DC offset capacitance. In the examples shown, this is conventionally achieved through a “breakout” (i.e. signal output and signal input between the amplifier stages) from the amplifier chip 2 to allow capacitance to be provided externally to the amplifier chip 2.

In FIG. 3, this breakout is provided by second stage connections 22. The output from the amplifier chip 2 for the second stage connections is provided by the preamp output channels 14 of the first stage. The input to the amplifier chip from the breakout for the second stage connections is provided by two ADC driver input channels 32. These then pass into the ADC driver stage 30, which also has two

ADC driver output channels 34, that are connectable in use to the ADC 500 shown in FIG. 2.

The first stage 10, ADC driver stage 30 and amplifier chip 2 shown in FIG. 3 have various other connections. These include power inputs, control inputs and some outputs. As is set out in more detail below, the control inputs are typically provided, in these examples by a portion of the amplifier chip that acts as a controller 60.

The THAT 6261 chip is able to be operated in a unipolar or bipolar configuration. When used according to an amplifier disclosed herein, the amplifier chip 2 is typically configured in a bipolar configuration. This arrangement provides the ability for a signal being amplified and being output to be able to have a negative value (e.g. negative voltage) as well as a positive value. If a unipolar configuration were used, depending on the power inputs, only negative values or only positive values could be handled.

As can be seen from FIG. 3, the amplifier chip 2 has positive 5 volts (V) (i.e. +5 V) and negative 5 V (i.e. −5 V) connections to the first stage 10, and +5 V and ground (GND, or 0 V) connections to the ADC driver stage 30, as well as +3.3 V and GND connections to the portion of the control 60 shown in FIG. 3. As set out in more detail below, suitable power connections are provided to the amplifier chip to allow it to be used. Each of the first stage and ADC driver stage also have their own capacitance breakouts to provide voltage decoupling for the internal components of each stage and to provide operation of the amplifier chip in the expected form.

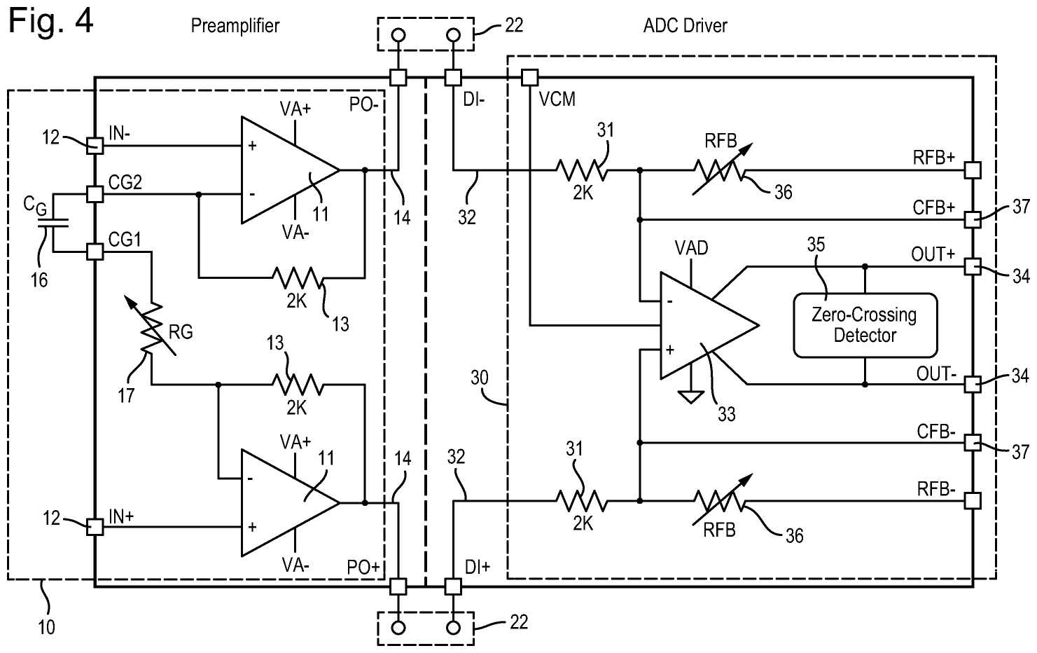

For example, FIG. 4 shows an illustrative version of the internal components of the first stage 10 and the ADC driver stage 30 as part of the amplifier chip 2. This figure shows the preamp input channels 12 each connecting to an operational amplifier 11 (op-amp), which have a resistance 13, in the form of a resistor in this example, connected between the negative input and the output of each op-amp.

The op-amp outputs provide the preamp output channels 14. The two op-amps have a connection between their negative inputs that includes a capacitor 16 and variable resistance 17. These components form a potential divider with the resistance connected between the op-amp negative inputs and their respective outputs. In this manner, the first stage provides a balanced differential preamp.

The preamp outputs pass to the second stage connections 22, which also include connections to the ADC driver inputs 32 for the ADC driver stage 30. These connect, via a resistance 31, to an op-amp 33 with two ADC driver output channels 34 with a zero-crossing detector connection 35 therebetween. A variable voltage to current conversion, RFB, 36 is also connected to each input of the ADC driver op-amp. This can be seen in FIG. 5. In use, these are connected to the ADC driver output channels to provide a potential divider with the resistance in the ADC driver inputs.

In use, the potential dividers of each of the first stage 10 and the ADC driver stage 30, and the variation included in them, allow the gain and/or functionality of each stage to be varied. These are typically adjusted by the controller 60 to set the appropriate gain amount or function.

Returning to FIG. 3, this shows a break in the illustrative circuit shown. This is because the THAT 6261 chip of which this figure represents a portion has a second set of preamp and ADC driver stages. These have the same connections and configuration as the first stage 10 and ADC driver stage 30 shown in FIG. 3. However, these are not required for the operation of an amplifier according to an aspect described herein, so are able to be excluded from the figures. Should a user wish to have an amplifier chip 2 capable of accepting multiple inputs and multiple outputs and for the inputs to be to have gain applied, then the second set of preamp and ADC driver stages could be used.

In other examples, the DC offset capacitance for which the breakout was originally provided can be addressed on chip. Since the second stage 20 is connected to the pins on the amplifier chip 2 provided for the DC offset breakout, should the DC offset capacitance be address on chip, a more invasive means of connecting the second stage would be needed, or a different design for providing the second stage. This could, for example, be provided by a designed in second stage or having each stage fully separated. However, such examples are intended to fall under the scope of an amplifier according to an amplifier disclosed herein.

FIGS. 5, 6A, 6B and 9 to 14 all show parts of a system through which an amplifier according to an aspect disclosed herein is able to be implemented. As such, the system corresponds to a system according to an aspect disclosed herein. These figures each include parts of a circuit diagram that interconnect. Various values are ascribed to many of the components depicted by the electrical circuit symbols included. While the values are purely illustrative, they are correct for a specific implementation of the system and amplifier 1. However, other values would still allow the system and amplifier to function. The values are represented in standard formatting, from which, for example, the capacitance or resistance, for the specific implementation may be derived. These values are intended to be example values only, and are not intended to be limiting on the scope of any aspect disclosed herein.

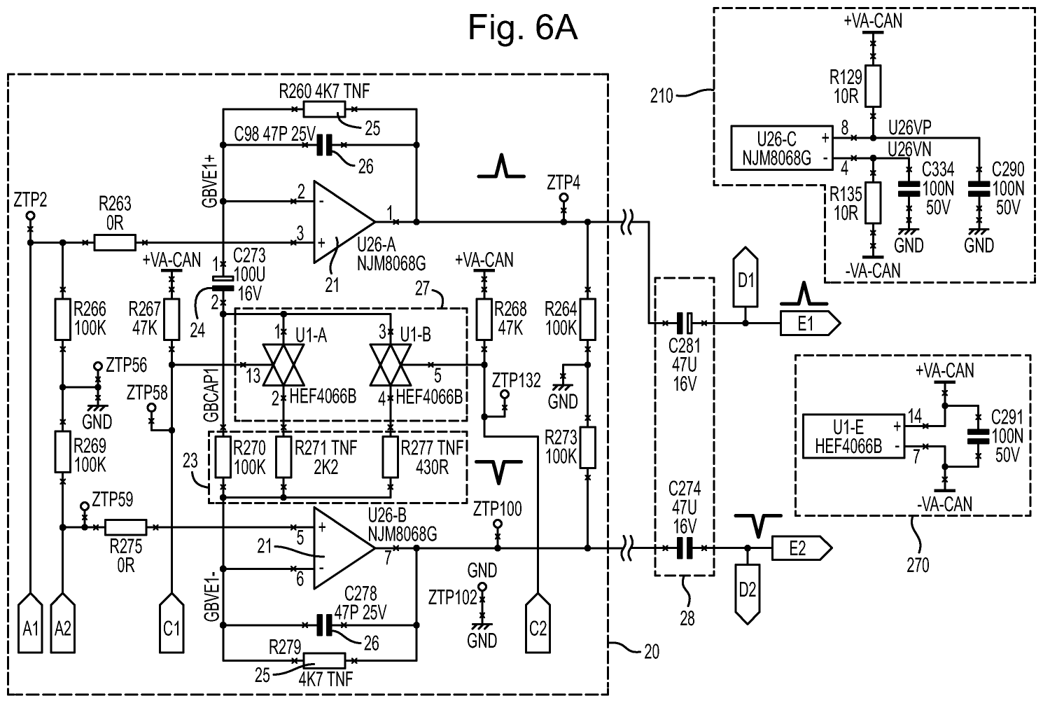

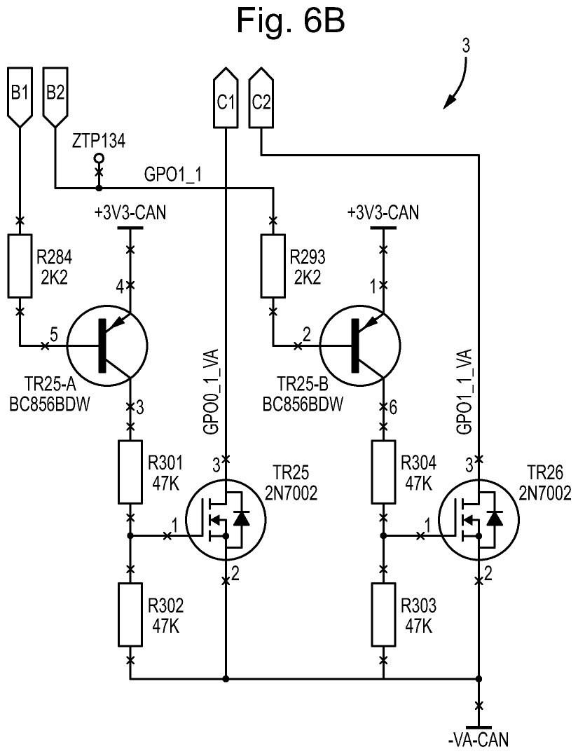

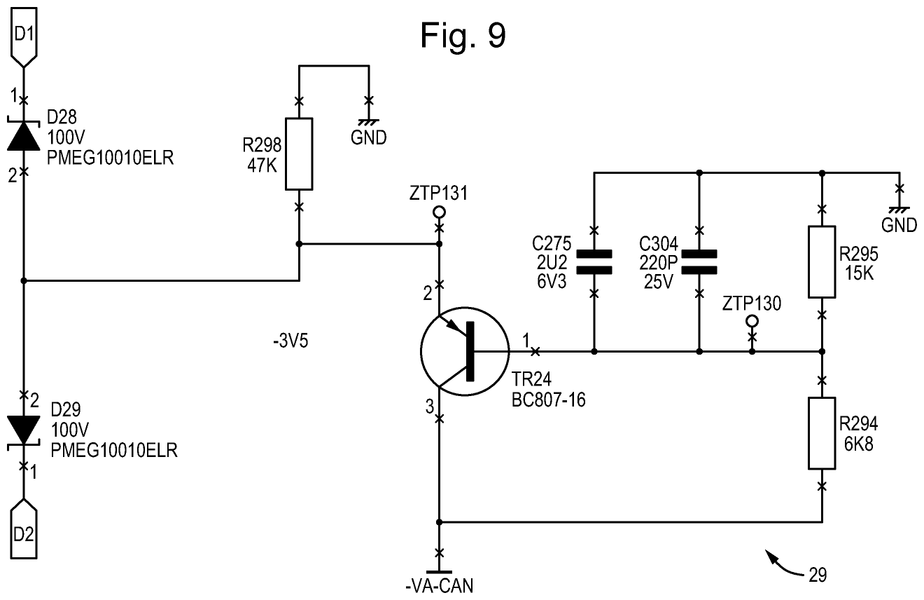

As a brief summary of how the circuits shown in FIGS. 5, 6A, 6B and 9 to 14 fit together, connections A1 and A2 in FIG. 5 provide an output to A1 and A2 in FIG. 6A. Connections B1 and B2 in FIG. 5 provide an output to B1 and B2 in FIG. 6B. In addition to inputs at A1 and S2, FIG. 6A receives further inputs at connections C1 and C2. These are provided by outputs C1 and C2 from FIG. 6B. Returning to FIG. 6A, this provides outputs at D1, D2, E1 and E2. E1 and E2 provide inputs to FIGS. 5, and D1 and D2 provide inputs to FIG. 9.

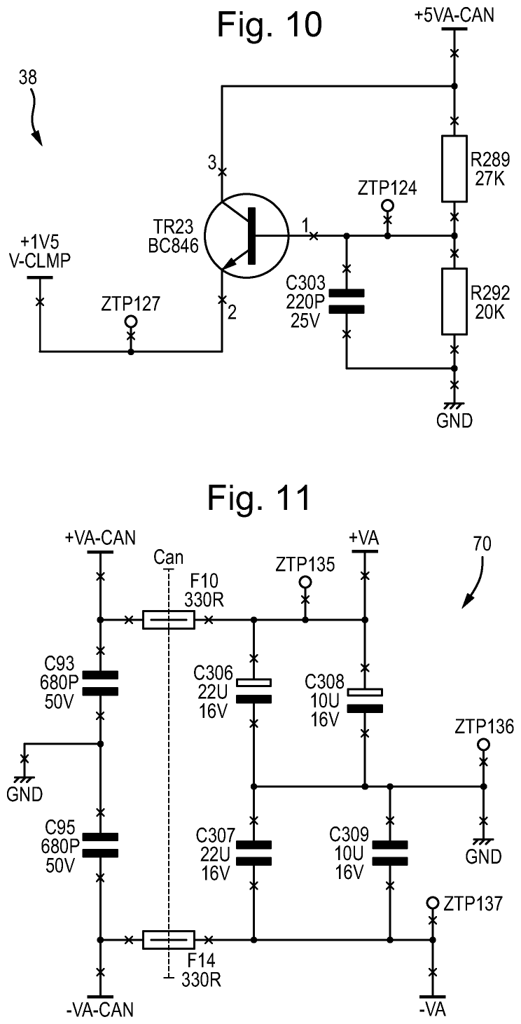

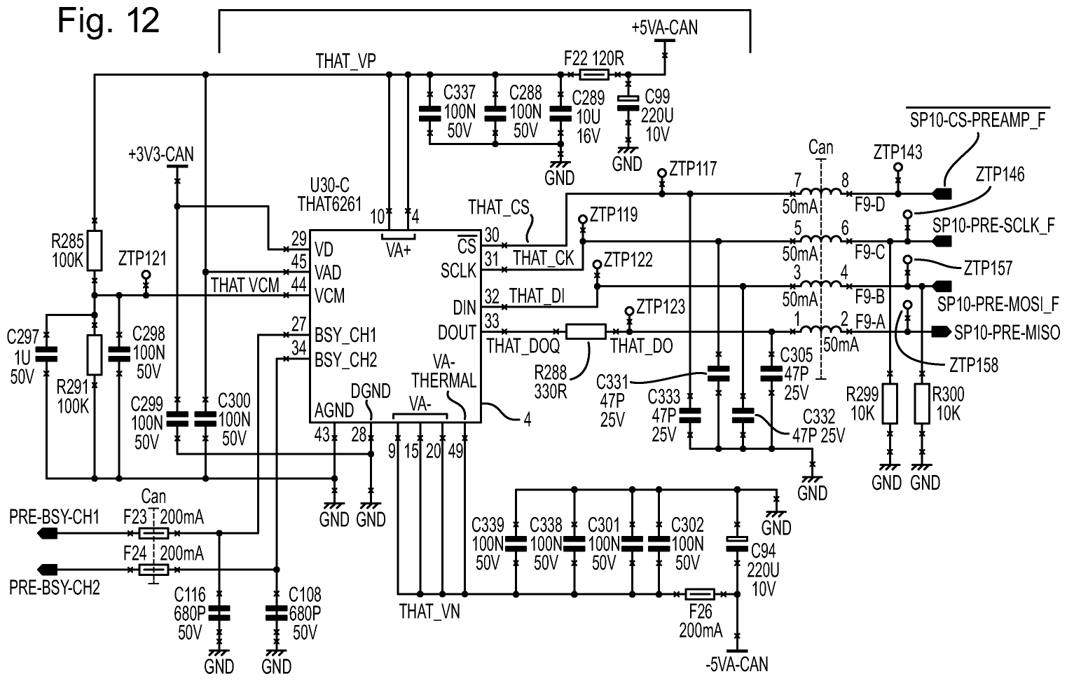

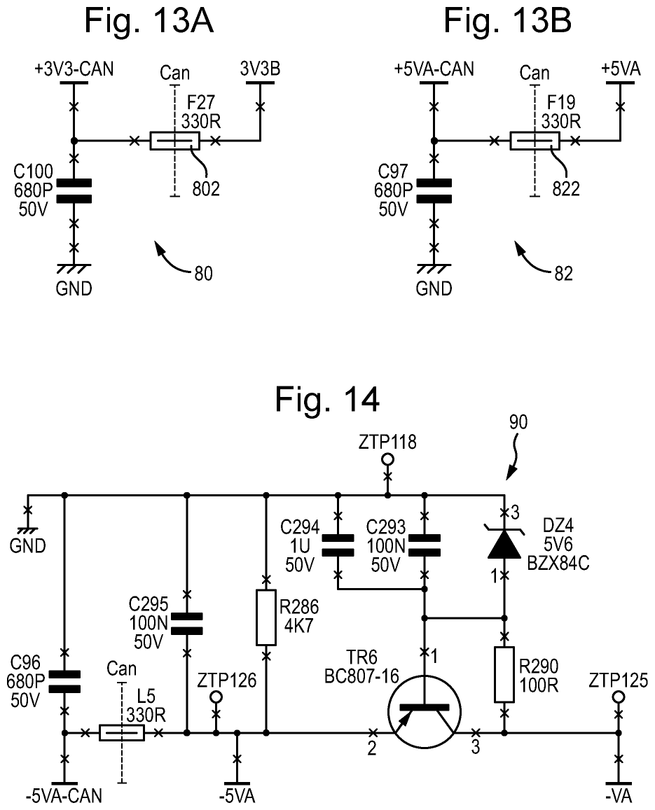

Turning to power connections, FIG. 10 is connected between a positive voltage source labelled +5VA-CAN and GND. This also has a connection of V-CLMP, which connects to the V-CLMP connection in FIG. 5. FIG. 11 is connected between a positive voltage source labelled +VA, positive voltage connection +VA-CAN, negative voltage source-VA, negative voltage connection-VA-CAN and GND. The −VA-CAN connection connects as a corresponding connection in FIG. 6A, in FIG. 6B and FIG. 9. The +VA-CAN connections connects as a corresponding connection in FIG. 6A. FIG. 13A has a positive voltage source 3V3B, positive voltage connection +3V3-CAN and a GND connection. FIG. 13B has a positive voltage source +5VA, positive voltage connection +5VA-CAN and a GND connection. FIGS. 6B and 12 have a positive voltage connection for +3V3-CAN, connecting them to FIG. 13A. FIG. 12 (and FIG. 10 as mentioned above) also has a positive voltage connection +5VA-CAN, which provides a connection to FIG. 13B. FIG. 14 has a negative voltage input-VA, a negative voltage connection −5VA-CAN and a GND connection. FIG. 12 has a negative voltage connection of −5VA-CAN; and FIGS. 6A, 9 and 12 also have GND connections.

FIG. 5 shows an example amplifier chip 2 with input and output pins. The audio signal input is provided from two inputs 40 into the chip. The capacitance 16 connected between the two preamp op-amps 11 shown in FIG. 3 can be seen in FIG. 5 between the audio signal input lines into the chip. The amplifier chip then has three groups of outputs and one further input. These are outputs A1 and A2 that pass to the second stage 20, shown in FIG. 6A; outputs B1 and B2 that pass to a switching control circuit 3 shown in FIG. 6b; outputs provided from the

ADC driver stage 30 to the amplifier output 50 that is connectable to the ADC; and inputs E1 and E2 from the second stage.

When implemented the control circuit 4 shown in FIG. 12 forms part of the same chip as the amplifier chip 2 shown in FIG. 5. While the audio signal is passed from the amplifier chip to the second stage 20 though outputs A1 and A2, a control signal originates in the control circuit 4 and passes out by outputs B1 and B2 via the amplifier chip 2.

In use, the audio input signal passes from audio signal inputs 40 into the amplifier chip 2 to the first stage 10. Gain is applied to the signal by the first stage at the level set by the control circuit 4. Due to how the audio signal is provided, each op-amp 11 of the first stage applies gain to one part of the audio signal, each part being phase offset by 180 degrees) (°).

The audio input signal to which gain has now been applied by the first stage 10 then passes through passes out of the amplifier chip 2 to the second stage 20 shown in FIG. 6A. This has two op-amps 21 connected to form a balanced differential amplifier. This means that with the signal from the first stage 10 arriving from inputs A1 and A2 and passes into the positive inputs of the op-amps of the second stage with each op-amp receiving one of the phase offset signals.

There is a resistance 23 connected between the negative inputs of the op-amps 21 of the second stage 20. This resistance also forms part of a potential divider, for which the other part is a resistance 25 connected between the negative input of the op-amp and the op-amp output for each op-amp. The potential divider can be provided by other components, such as any that provide an impedance.

In terms of effect on functionality of the op-amps 21, the resistance 25 connected between the negative input to each op-amp and the respective op-amp output, is a feedback resistance. In use, the op-amp, if not connected with resistors, would match voltage of the negative input to that of the positive input, when the positive input is provided with a signal.

By connecting the feedback resistance 25 as set out above and connecting the resistance 23 between the negative inputs of the op-amps 21, as set out above, two potential dividers, each with an output to the negative input of one of the op-amps, are formed. This means that when a signal is provided to the positive input of one op-amp (as is the case when a signal is provided from the first stage 10 from the amplifier chip 2 at inputs A1 and A2 in FIG. 6A), the op-amp modifies its output. This is, within the bandwidth capabilities of the op-amp, to try to keep the negative input of the op-amp at the same voltage as is instantaneously being provided to the positive input.

Taking an illustrative example, an arrangement could be provided with a potential divider in place with one side connected to the output of the op-amp as well as to the negative input with a resistance in between. A second side of potential divider is connected to ground and the negative input with a resistance in between. Should each side of the potential divider have a 4.7 kΩ resistor, when a signal is provided to the positive input of the op-amp, the negative input, which follows the positive input, registers half the voltage value of the signal provided to the positive input. As a result of this, the output signal of the op-amp at its output is doubled, thereby amplifying the positive input signal by two, thereby produce two times gain amplification. Returning to the example shown in FIG. 6A, the gain produced at the op-amp 21 output is determined by resistance on each side of the potential divider. This demonstrates that the variable nature of the resistance 23 connected between the negative inputs of the op-amps is what causes the ability of gain variation in the second stage 20. Due to the bipolar configuration of the second stage, the gain producible by the second stage is doubled. This is because the gain applied by one op-amp in a positive voltage direction is matched by the same gain applied by the other op-amp in a negative voltage direction.

In addition to the resistance 23 connected between the negative inputs of the two op-amps 21, there is a capacitance 24 connected in series with the resistance. This reduces DC blocking between the two op-amps. Additionally, each op-amp has a capacitance 26 connect across it (so between the negative input and the output of each op amp). This provides RF (Radio Frequency) protection and shielding from the likes of TDMA (time division multiple access) noise. This is achieved by reducing the effect of, or increasing the immunity to, external signals of high frequency (such as one many times larger than the frequency of audio signals). Without the capacitance, this could cause the op-amp to clip or could cause the op-amp to become unstable due to being excited by the high frequency of such a signal. These types of signals are outside of the frequency range of interest, so this capacitance reduces the sensitivity of the op-amp at such frequencies, for example at about 100 kilohertz (kHz), which can be a minimum frequency against which this capacitance would provide shielding.

The capacitance 26 also reduces the bandwidth of the op-amp 21 that it is connected across. Considering the signal received by the op-amp, the higher the frequency of the signal received, the less effective the op-amp becomes because to this capacitance. This means the gain will reduce. Due to this, the capacitance effectively short circuits out the resistance 25 connected between the negative input of the op-amp and the op-amp output. The reason to do this is that as the gain increases on the op-amp, the phase angle changes. Once the gain increases to a particular point, the phase angle of the output signal will be 180° phase shifted compared to the input signal. When this phase shift is reached, the op-amp starts oscillating and will simply amplify its input in phase and feedback. This is the same effect as that which occurs when a microphone is placed too close to a speaker, which produces a loud, high pitch, noise emitted due to the feedback this causes. To avoid this, the capacitance 26 functions, such that, by the time the gain or frequency gets to the stage where, when the phase angle is 180°, the gain is so low that the op-amp will not oscillate. This thereby increases the stability of the op-amp (or, in other words, reduces the instability of the op-amp) by the shorting of the resistance 25.

Overall, the configuration of the op-amps 21 in the second stage and the corresponding potential dividers and capacitances provides a non-inverted op-amp circuits. In other examples, some or all of these supplementary components (i.e. non op-amp and intervening impedance provided by the resistors in the example shown in FIG. 6A) may be excluded or replaced with other components or components offering different levels of resistance or capacitance as appropriate.

The op-amps 21 used in the second stage 20 shown in FIG. 6A are NJR NJM8068 op-amps. These were chosen due to a balance of their maximum gain range, noise performance and relative cost. In other examples, other op-amps are able to be used.

The different gain levels identified above that are able to be applied by the second stage 20 are achieved in the examples shown by modifying the value of the resistance 23 connected between the op-amps 21. In some examples a variable resistor would be able to provide this functionality. However, variable resistors only exist as analogue components, so would not typically be able to be digitally controlled. Since digital control may offer more reliable, repeatable and accurate application of gain, in the example shown in FIG. 6A, instead, there is provided a minimum fixed resistance to which analogue switches 27 are connected in series with a resistor. In the example shown in FIG. 6A, there are two switches. In other examples, there may be more switches connected in series with resistors. These switch-resistor pairs are connected in parallel with each other and with a primary resistor connected between the op-amps to provide the minimum fixed resistance. The three gain levels able to be achieved with the second stage are able to be implemented by switching different combinations of these switches between on and off states.

At the minimum gain level both of the two switches 27 are in an off state. This means only a single resistor of the resistance 23 connected by between the op-amps 21 of the second stage 20 is functionally connected to the circuit. Due to the value of this resistance in the example shown in FIG. 6A (100 kΩ), this provides a gain of about 1 dB.

In the mid-gain level able to be applied by the second stage 20 using the arrangement shown in FIG. 6A, one switch of the switches 27 is in an “on” state. This is the switch connected to the larger resistor of the resistance 23 attached to each switch (in the example shown in FIG. 6A, this is the 2.2 kΩ resistor), and the other switch is in an “off” state. This then provides two resistors functionally connected to the circuit in parallel, and, as such, reduces the overall resistance placed on the circuit.

At the highest gain level able to be applied by the second stage 20 using the arrangement shown in FIG. 6A, both switches 27 are in the “on” state. This provides three resistors (so now also including the 430 Q resistor shown the example in FIG. 6A) functionally connected, in parallel. In other examples, the gain levels may be achieved in a different manner, or with a different number of switches or different combination of on and off states.

In the examples shown in the figures, by switching the switches 27 to an “on” state, the resistance connected between the op-amps 21 is reduced due to the resistors being connected in parallel. This causes the gain to increase.

In the example shown in FIGS. 6A, the switches 27 are driven by the same firmware that drives the amplifier chip 2 due to being connected to two general outputs at B1 and B2 from the amplifier chip 2. This provides inputs B1 and B2 shown in the example switching control circuit 3 shown in FIG. 6B. The switching control circuit shown in FIG. 3 includes two channels, one dedicated to each switch 27. Each channel includes transistors and two sets of resistance. One set of resistance provides some impedance in the circuit for a signal prior to reaching a first transistor, which is provided in the example shown in FIG. 6B by a bipolar junction transistor (BJT). This is a P-channel BJT with its emitter connected to the +3V3-CAN voltage connection, its base connected to the signal input from the amplifier chip 2 (and therefore the control circuit 4) and its collector connected to the second resistance set. The second resistance set is configured as a potential divider with its output being provided to the gate of the second transistor, and has a positive voltage connection from the BJT and a negative voltage connection to the −VA-CAN connection. The second transistor is an N-channel MOSFET with its source connected to the −VA-CAN connection and its drain connected to the output from the switching control circuit C1 or C2 to provide the input to the switches in the second stage 20. Of course, in other examples, this switching control circuit may be implemented in an alternate or modified manner.

In other examples, the firmware may drive the switches 27 independently of the amplifier chip 2, and indeed, in various examples, there may be a separate controller (e.g. separate firmware) for the switches to the controller 60 (e.g. firmware) used to operate the amplifier chip 2. Further, in some examples, the switches are optional, and the gain able to be applied by the second stage 20 may be fixed at a predetermined amount, such as when the user knows they will always use the amplifier with the same input, such as the same microphone, instrument or device.

Additionally, as mentioned above, the number so switch-resistor pairs can be adjusted while allowing the second stage 20 to still provide the same gain range. However, we found that the number of steps across gain range effects how smooth the noise curve of the amplifier 1 is. FIG. 7 shows a plot of system gain level in dB against dynamic range in dB, which, as set out above, represents the signal to noise ratio identifiable in an output signal.

The plot in FIG. 7 includes lines provided by four data sets based on examples of using a THAT 6261 amplifier chip with and without various implementations of the second stage 20. The first line 5 represents the response of an example with only the THAT 6261 amplifier chip. As such, this shows a gain range of −8 dB to +34 dB. The line has small oscillations due to the 1 dB increments by which the gain is modified in the THAT 6261 chip. The dynamic range stays at its initial 110.0 dB at a system gain of −8 dB dropping to 108.0 dB at about +23 dB of system gain in a curve with increasing gradient as the system gain approaches about +23 dB. This then drops to a dynamic range of about 101.0 dB in a curve up to a system gain of +34 dB.

The second line 6 in the plot shown in FIG. 7 represents the response of a calculated (digital signal processing, DSP) ideal gain v dynamic range (DNR) for −8 dB to 70 dB gain as a comparative example for the first line 5, third line 7 and fourth line 8. This second line matches the first line between −8 dB and +34 dB, but without the small oscillations due to gain increments. From a system gain of +34 dB up to a system gain of +70 dB, the second line is linear, dropping to a dynamic range of about 65.0 dB by +70 dB.

The third line 7 in the plot shown in FIG. 7 represents the response of a THAT 6261 amplifier chip with a second stage 20 with two switches as set out above and as shown in FIG. 6A. In this example the overall amplifier the THAT chip and second stage provides has gain steps caused by operation of the switches 27 in the second stage at a system gain of +38 dB and +52 dB.

The third line 7 is shown with a start at a system gain of-4 dB with a dynamic range of about 109.0 dB. This curves in a similar manner to that of the first line 5 to a dynamic range of about 101.0 dB, which matches that of the first line at a system gain of +34 dB. As with the first line, this third line also have the minor oscillations due to the 1 dB gain increments achievable along its entire length. From a system gain of +34 dB to +38 dB, the third line follows the second line 6. Over the system gain range of +38 dB to about +39 dB, the dynamic range drops from about 97 dB to about 94 dB, appearing as a step down away from the ideal curve of the second line. The dynamic range of the third line has a shallower gradient than the ideal curve of the second line from a system gain of about +39 dB to +52 dB. This causes the third line move towards the second line and to intersect the second line at a dynamic range of about 88 dB at a system gain of about +47 dB. This shallower gradient continues, but the third line does not deviate from the ideal curve by more than about 0.5 dB of dynamic range up to a system gain of +52 dB. At a system gain of +52 dB to about +53 dB, there is another step down in dynamic range from 84 dB to 80 dB. This again drops the dynamic range below the ideal curve of the second line by about 2 dB. However, the third line curves to bring it approximately in line with the ideal curve of the second line at a system gain of +60 dB and dynamic range of about 76 dB up to the end of the curve at a system gain of +68 dB and dynamic range of about 68 dB.

The fourth line 8 in the plot shown in FIG. 7 represents the response of an example THAT 6261 amplifier chip with a second stage 20 with only a single switch. In this example, the overall amplifier the THAT chip and second stage provides has gain steps caused by operation of the switches 27 in the second stage at a system gain of +38 dB. The fourth line only has minor differences to the third line 7 between a system gain of −4 dB and +38 dB. At this point, due to the switching of the gain in the single step, the dynamic range drops from about 97.0 dB to about 85.0 dB, and it can be seen from FIG. 7, that the system gain decreases slightly, such as by about 0.5 dB to 1.0 dB. From a dynamic range of about 85 dB and system gain of about 38 dB, there is then a curve that intersects with the ideal curve of the second line 4 and the third line at a system gain of about +62 dB and dynamic range of about 73 dB. From this point to the end of the fourth line at a system gain of about +68 dB and dynamic range of about 68 dB, the fourth line approximately matches the third line and ideal curve of the second line.

However, instead of the curve being smooth with minor oscillations like the first line 5 and third line, as is the case up to a system gain of +38 dB, between a system gain of about +38 dB to about +56 dB, there are more significant, but diminishing amplitude, oscillations in the dynamic range as the system gain increases. These oscillations start with an amplitude of about 2 dB of dynamic range over a period (or wavelength) of about between 3 dB and 4 dB of system gain returning to the minor oscillations of the third line by a system gain of about +53 dB.

From this it can be seen that the steps in the dynamic range produced when two switches 27 are used are relatively small, and therefore have a minimal effect on the quality of the output. However, it can also be seen that when using only a single switch, there is a step of a significant size in the dynamic range. This is undesirable. As such, and amplifier according to an aspect disclosed herein may have at least one stage arranged, in use, to provide modifiable gain that is modified in two or more steps across the gain range of that stage.

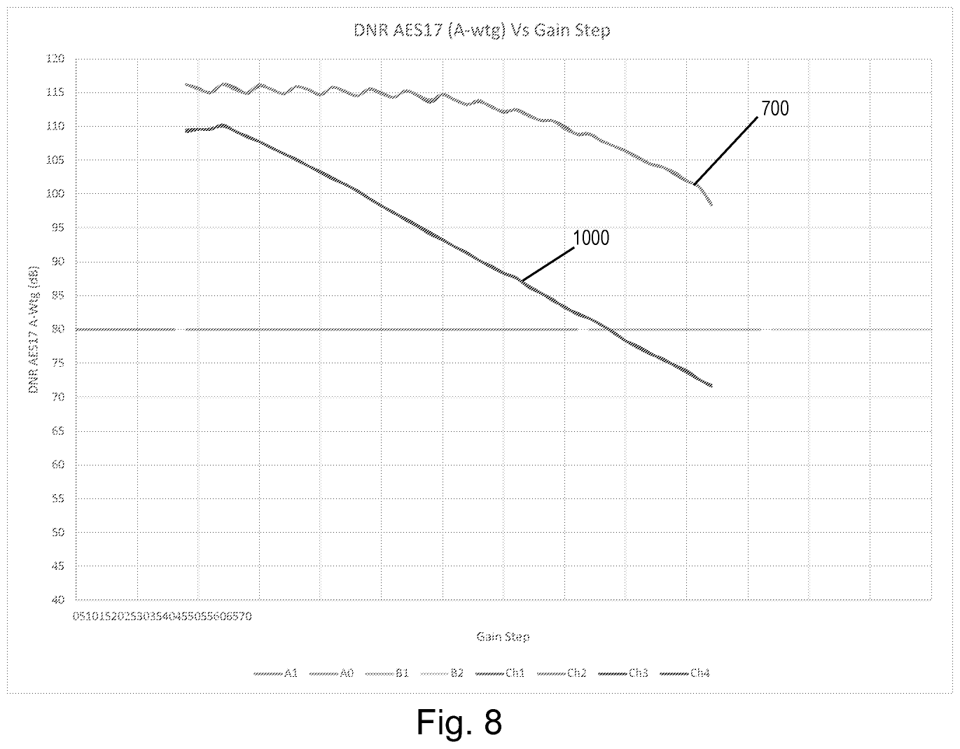

As a further comparison of differences in dynamic range, FIG. 8 shows a plot with two lines. This plot includes lines provided by two data sets based on examples of using a Focusrite Scarlett 2i2 4th Gen audio interface, which implements the THAT 6261 amplifier chip with and without an external microphone booster in the form of an sE Electronics DM1 Dynamite. This means the plot in FIG. 8 provides a comparison of an example dynamic range available in an amplifier according to an aspect described herein against a known amplifier.

The upper line 700 shown in FIG. 8 represents the response of an example with only the Focusrite Scarlett 2i2 4th Gen audio interface, which includes the THAT 6261 amplifier chip. The gain range represented is a gain range of +8 dB to +53 dB. The line has small oscillations due to the 1 dB increments by which the gain is modified in the THAT 6261 chip. The dynamic range stays at its initial 115.0 dB at a system gain of +8 dB dropping to about 113.0 dB at about +35 dB of system gain in a curve with increasing gradient as the system gain approaches about +35 dB. This then drops to a dynamic range of about 101.0 dB in a linear manner up to a system gain of +52 dB. There is then a final drop to a dynamic range of +98 dB at a system gain of +53 dB.

The lower line 1000 shown in FIG. 8 represents the response of an example with the Focusrite Scarlett 2i2 4th Gen audio interface that includes the THAT 6261amplifier chip and to which the sE Electronics DM1 Dynamite (a +28 dB gain booster) is connected to an input. The gain range represented matches that of the upper line 700, so covers a gain of +8 dB to +53 dB. From a gain of +8 dB to +12 dB, the dynamic range is approximately constant at about 110 dB. The dynamic range then drops in a linear manner as the system gain increases to +53 dB where the dynamic range is about 72 dB.

By comparing the dynamic range of the two arrangements, the dynamic range of an example implementation according to an aspect described herein has enhanced dynamic range performance relative to an example known system. This validates the improved signa-to-noise performance of using an amplifier according to an aspect described herein.

Returning to the implementation detailed in FIG. 7 and other figures, regardless of how many switches 27 are used in the second stage 20, the switches shown in FIG. 6A are NXP Semiconductors HEF4066B analogue switches. These are chosen due to being low cost, while also being able to operate under the conditions applied at this point in the circuit. Other switches may be used in other examples.

The amplified signal received by the second stage 20 from the amplifier chip 1 (from the first stage 10), is amplified in the manner set out above and output from the op-amps 21. In some examples, the signal is returned to the ADC driver stage 30 at this point without further processing via outputs E1 and E2 from FIG. 6A to inputs E1 and E2 in FIG. 5. In the example shown in FIG. 6A, the signal instead passes to two capacitors 28. These provide DC offset or DC blocking capacitors for which the breakout from the amplifier chip 1 is originally provided. After passing through these capacitors, the signal is then passed to the ADC driver stage in the examples shown herein.

As indicated by the breaks between the second stage 20 and DC offset capacitors 28 shown in FIG. 6A, one or more other components, functional blocks and/or features may be included in the circuit between the intermediate stage and DC offset capacitors. In some examples, the DC offset capacitors may be optional.

The amplifier 1 according to an aspect is typically a current amplifier. As set out above, the first stage 10 and the second stage 20 are directed to providing gain to amplify and attenuate signal received by the amplifier. This is instead of other functions an amplifier stage can have, such as filtering, adjusting tone or providing a driver for an ADC (as is the case for the third, ADC driver, stage 30).

In the example shown in FIG. 6A, as well as the DC offset capacitors 28, there are outputs D1 and D2 upstream of the outputs E1 and D2. These provide the inputs at D1 and D2 in FIG. 9. FIG. 9 shows an example clamp circuit 29 is applied between the two signal lines (i.e. connected so as to join the negative and positive signal lines passing out of the DC offset capacitors 28 to the ADC driver stage 30). The clamp circuit is intended to be a protection circuit and can be implemented in an alternative manner in other examples. In the example shown in FIG. 9, this provides a clamp voltage of negative 3.5 V. This means that if a signal is greater than 3.5 V at this point in the circuit, it is clamped to 3.5 V. This limits the ability for the amplifier chip 1 to become latched as it may do if signals with higher voltages were able to pass to the amplifier chip 2, and can be provided by any suitable form of clamp circuit. In some examples, clamp circuit is an optional feature and not required to allow the second stage 20 to function.

Whether or not the clamp 29 or DC offset capacitors 28 are present, once the signal passing through the second stage 20 has gain applied to it by the op-amps 21, the signal is passed, via outputs E1 and E2 shown in FIG. 6A to inputs E1 and E2 shown in FIG. 5. The signal is then passed through the ADC driver stage 30, where it is processed as set out above and passed along ADC outputs 34 to amplifier output 50, where it, in some examples, is connected to an ADC 500.

The outputs from the ADC driver stage 30 from the amplifier chip 2 example shown in FIG. 5 include a clamped output 37. As shown in FIG. 4, these clamped outputs connect to the positive input and negative input of the op-amp 33 of the ADC driver stage. These connections are electrically connected to clamp circuit 38 shown in FIG. 9. This provides a clamp voltage of positive 1.5 V. This means that if the signal is maintained at or above a threshold of 1.5 V. This is an optional feature not required to allow the ADC driver stage to function and may be implemented in any suitable form of clamp circuit.

FIG. 12 shows the power and control element of the amplifier chip 2, also referable to as the controller 60, control chip 4 or a portion thereof. This is a more detailed representation of the serial interface shown at 60 in FIG. 3, or a portion that connects to that serial interface. In use, an external controller interfaces with the power and control element. In the examples set out herein this is the firmware operating within the wider amplifier system in which the amplifier 1 and amplifier chip 2 sits. In other examples, this may be a form of software, firmware, user operation or other form of control or controller. As mentioned above, the amplifier 1, including each of the first stage 10, second stage 20, ADC driver stage 30 and complementary components are controlled via this. This may also be achieved differently in different examples.

As such, it is via the power and control element shown in FIG. 12 that the second stage 20 gain level is managed, controlled, determined, set, operated, modulated, adjusted and modified. This also applies to the first stage 10 gain level, which is managed, controlled, determined, set, operated, modulated, adjusted and modified through this element.

The portions of the circuit shown in FIGS. 11, 13A, 13B and 14, and sections 210 and 270 of FIG. 6A are power supply filters. These supply the portions of the circuit to which they are connected in the configurations set out above with power. The filtering provides power with low noise levels that is clean (i.e. having a well-defined form) and has good immunity to outside interference. These are all relatively standard parts of filter circuitry that would be added to any number of audio preamp circuits. The specific form of these power supply filters can be varied while still performing their function.

In FIG. 6A, the op-amps 21 of the second stage 20 have a power supply provided by circuit portion 210. Similarly, the switches 27 have a power supply provided by circuit portion 270. Each of these has decoupling capacitance connected across the rails. In the op-amp power supply, this capacitance is connected between the positive voltage source and a GND connection and the negative voltage source and a further GND connection along with some resistance. In the switch power supply, the capacitance is connected between the positive voltage source and negative voltage source. This implementation of capacitance reduces noise that is picked up locally to the op-amps or circuit to increase immunity of the op amps and the switches to external noise or noise in the power being supplied.

FIG. 11 shows filter 70. This is configured to limit noise passing into the amplifier circuit 2 and control circuit 4 from the power supply. Since the amplifier circuit is intended to limit noise being incurred in the audio signal to which gain is being applied, limiting noise from the power supply reduces the affect the power supply to the circuit has on this.

Considering the filter 80 shown in FIG. 13A and the filter 82 shown in FIG. 13B, these are passive filters attached to power supply lines. These each have an inductor 802 and 822 connecting the respective voltage sources and the GND and voltage output connections. The implementation of these inductors reduces high frequency noise going into the respective circuit.

FIG. 14 is a power supply 90. This provides a −5.0 V power supply to the amplifier chip 2 (via the control circuit 4). This allows the amplifier chip to be set up in a bipolar configuration. By using the bipolar configuration, less decoupling capacitors need to be used and also allows the chip components to be at 0.0 V when there is no signal passing through it instead of being at a half rail voltage (so, in this case about +2.5 V). Further the power supply reduces the power it receives at −6.5 V to −5.0 V.

1. An amplifier for amplifying audio signals, comprising:
a plurality of stages, at least two of the stages of the plurality of stages being connected in series and each of the at least two stages being a gain stage each provided by a preamplifier stage, the at least two stages being arranged, in use, to apply gain to an input signal provided to the amplifier.

2. The amplifier according to claim 1, wherein the amplifier is a preamplifier.

3. The amplifier according to claim 1, wherein the plurality of stages includes an analogue to digital converter, ADC, driver stage.

4. The amplifier according to claim 3, wherein at least one stage of the at least two stages and the ADC driver are part of an integrated circuit.

5. The amplifier according to claim 4, wherein a further at least one stage of the at least two stages is connected between a first output of the integrated circuit and a first input of the integrated circuit, the first output and first input being between the at least one stage and ADC driver of the integrated circuit.

6. The amplifier according to claim 5, wherein the first output and first input of the integrated circuit are terminals of the integrated circuit.

7. The amplifier according to claim 5, wherein the integrated circuit includes a second output connected to a control input of the at least one stage connected between the first output and the first input of the integrated circuit, the at least one stage connected between the first output and the first input of the integrated circuit being arranged, in use, to be controllable based on a signal issued from the second output of the integrated circuit.

8. The amplifier according to claim 1, wherein the at least two stages are arranged in use to selectively apply gain to the input signal.

9. The amplifier according to claim 8, wherein the at least two stages are arranged in use to apply modifiable gain to the input signal.

10. The amplifier according to claim 9, wherein the at least two stages include a first stage and a second stage.

11. The amplifier according to claim 10, and wherein the first stage and the second stage each have a gain range, the first stage having a different gain range to the second stage.

12. The amplifier according to claim 11, wherein the input signal provided to the amplifier passes to the first stage before passing to the second stage, the gain range of the first stage being greater than the gain range of the second stage.

13. The amplifier according to claim 11, wherein the gain of the first stage and the gain of the second stage are modifiable in gain steps, the gain steps of the first stage are smaller than the gain steps of the second stage.

14. (canceled)

15. The amplifier according to claim 10, wherein the second stage is a differential amplifier including a potential divider having a first impedance and a second impedance separated by an output of the potential divider, at least one of the first impedance and the second impedance is a variable impedance.

16. The amplifier according to claim 15, wherein the variable impedance includes a plurality of impedances connected in parallel, each of at least one of the impedances of the plurality of impedances is connected to a switch operable, in use, to set connectivity of the respective impedance.

17. (canceled)

18. The amplifier according to claim 10, further comprising a controller arranged, in use, based on user input of a gain level, to set the gain of the at least two stages.

19. (canceled)

20. (canceled)

21. The amplifier according to claim 1, wherein the plurality of stages are arranged, in use, to maintain input signal provided to the amplifier, when provided as an analogue signal, as an analogue signal.

22. (canceled)

23. The amplifier according to claim 1, wherein the plurality of stages include:
a first stage configured as a preamplifier and arranged in use to receive an input signal and to output an amplified signal;
a second stage configured as an analogue to digital (ADC) drive and arranged in use to issue an output signal; and
an intermediate stage configured as a preamplifier and connected between an output of the first stage and an input of the second stage, thereby receiving the amplified signal, wherein the intermediate stage is arranged in use to apply secondary amplification to the amplified signal and output a further amplified signal, the second stage being arranged to receive the further amplified signal as an input; and
the amplifier further comprises a controller arranged in use to select a gain level to be applied by the intermediate stage, thereby modifying a cumulative gain across by the amplifier.

24. A system for amplifying audio signals, the system comprising:
an audio signal input;
an amplifier according to claim 1, the amplifier comprising a plurality of stages, at least two of the stages of the plurality of stages being connected in series and each of the at least two stages being a gain stage each provided by a preamplifier stage, and an output, the plurality of stages being connected between the output and the audio signal input, wherein the at least two stages are arranged, in use, and to apply gain to an input signal provided to the audio signal input;
an ADC connected to the output of the amplifier; and
an output connected to the ADC and connectable, in use, to an output device;
the output being connected to the ADC.

25. The system according to claim 24, further comprising a controller connected to the amplifier, the controller arranged, in use, based on user input to control operation of the amplifier.
